(19) United States
(12) Patent Application Publication
(10) Pub. No.: US 2024/0279812 A1
(43) Pub. Date: Aug. 22, 2024

(54) VACUUM PROCESSING SYSTEM AND PROCESS CONTROL

(71) Applicant: VAT HOLDING AG, Haag (CH)

(72) Inventors: Frantisek BALON, Sevelen (CH); Kerim YUNT, Zürich (CH); Dominic MAYRHOFER, St. Gallen (CH)

(21) Appl. No.: 18/559,997

(22) PCT Filed: May 6, 2022
(86) PCT No.: PCT/EP2022/062313

§ 371 Date: Nov. 9, 2023

(30) Foreign Application Priority Data
May 11, 2021 (DE) 10 2021 002 479.6

(51) Int. Cl. C23C 16/52; C23C 16/44; C23C 16/455

(52) U.S. Cl. CPC C23C 16/52; C23C 16/4412; C23C 16/45561

(57) ABSTRACT

Disclosed is a vacuum processing system including a vacuum chamber, a controllable fluid application arrangement connected to the vacuum chamber and configured to provide inflow of fluid into the vacuum chamber in controlled manner and a controlling and/or regulating unit for controlling at least the controllable fluid application arrangement. The vacuum processing system comprises an atmospheric analyzer, the atmospheric analyzer is arranged and configured to determine atmospheric information of inside of the vacuum chamber and to provide the atmospheric information as a respective atmospheric signal and the controlling and/or regulating unit is configured to control the controllable fluid application arrangement as a function of the atmospheric signal.

The invention relates to a vacuum processing system comprising at least a vacuum chamber, a fluid application unit, a controlling unit and an atmospheric analyser.

Known vacuum processing systems are widely used for instance in the field of IC, semiconductor or substrate manufacture, which has to take place in a protected atmosphere, as far as possible without the presence of contaminating particles.

Vacuum-chamber systems of such a type comprise, in particular, at least one evacuable vacuum chamber which is provided for receiving semiconductor elements or substrates to be processed or produced and which has at least one vacuum-chamber opening, through which the semiconductor elements or other substrates can be conducted into and out of the vacuum chamber. Typically, at least one vacuum pump for evacuating the vacuum chamber and at least one gas inlet valve for applying a process gas are provided. For instance, in a manufacturing plant for semiconductor wafers or liquid-crystal substrates the highly sensitive semiconductor elements or liquid crystal elements pass sequentially through several process vacuum chambers in which the parts located within the process vacuum chambers are treated in each instance by means of a treatment device. Both during the treatment process within the process vacuum chambers and during the transportation from chamber to chamber, the highly sensitive semiconductor elements or substrates have to be located at all times in a protected atmosphere—in particular, in an airless environment.

Since the substrates to be produces by means of an aforementioned system are of highly sensitive quality e.g. the generation of particles—caused, in particular, by the actuation of a vacuum or inlet valve or by a transportation system—and the number of free particles in the vacuum chamber have to be kept as low as possible. The generation of particles typically is a consequence of friction, for instance as a result of metal/metal contact and as a result of abrasion.

For that, specifically designed vacuum valves, such as vacuum regulating valves or transfer valves find application in the production of the sensitive semiconductor elements.

A vacuum-regulating valve is employed for the purpose of setting a defined process environment (e.g. pressure) in a process chamber. A closed-loop control may be undertaken on the basis of a pressure signal, which provides information about the internal pressure of the chamber, and on the basis of a target variable—that is to say, a nominal pressure—which is to be obtained by means of the closed-loop control. The position of a valve shutter (valve disc) is then varied within the scope of the closed-loop control in such a way that the nominal pressure is obtained within a definite period of time.

Processing of a substrate, e.g. for producing a semiconductor, has to be performed under well-defined and controlled conditions. Such processing may in particular comprise deposition of atomic or molecular layers on the substrate.

Chemical vapour deposition (CVD) is a vacuum deposition method and can be applied to produce the highly sensitive substrates. The process is often used in the semiconductor industry to produce thin films. In typical CVD, the wafer (substrate) is exposed to one or more volatile precursors, which react and/or decompose on the substrate surface to produce the desired deposit.

Atomic layer epitaxy or more generally known as atomic layer deposition (ALD) is a thin-film deposition technique based on the sequential use of a gas-phase chemical process. That process is also often used in the semiconductor industry to produce thin films. The majority of ALD reactions use two chemicals called precursors (also called reactants). These precursors react with the surface of a material one at a time in a sequential, self-limiting, manner. A thin film is slowly deposited through repeated exposure to separate precursors. ALD has become a key process in fabricating semiconductor devices and is also used for synthesising nanomaterials.

During atomic layer deposition a film is grown on a substrate by exposing its surface to alternate gaseous species (typically referred to as precursors). In contrast to chemical vapour deposition, the precursors are not present simultaneously in the reactor, but they are inserted as a series of sequential, non-overlapping pulses. In each of these pulses the precursor molecules react with the surface in a self-limiting way, so that the reaction terminates once all the reactive sites on the surface are consumed. The maximum amount of material deposited on the surface after a single exposure to all of the precursors (a so-called ALD cycle) is determined by the nature of the precursor-surface interaction. By varying the number of cycles it is possible to grow materials uniformly and with high precision on arbitrarily complex and large substrates.

A sister technique of atomic layer deposition, molecular layer deposition (MLD), is employed when organic precursors are wished to be used. By combining the ALD/MLD techniques, it is possible to make highly conformal and pure hybrid films for many applications.

A further surface processing technique is called atomic layer etching (ALE) which may be understood to provide an effect opposite to deposition of material. Material is removed from a substrate by performing atomic layer etching. Here, reactants are used to attack the surface or material which is being removed.

One requirement for reliably performing one of above deposition processes or any other process inside of a vacuum chamber is to provide an atmosphere inside of the vacuum volume (chamber) which corresponds to a nominal (target) atmospheric state for the respective process.

For instance, volatile by-products may be produced during a deposition cycle which makes use of applying a plasma in the chamber. Moreover, a first precursor may (in-part) still be present when initiating a succeeding processing step for which (exclusively) a second precursor should be used.

Such processual contaminations are typically tried to be avoided by removing of unwanted fluids (e.g. precursor) by gas flow through the reaction chamber for a defined time period. A first process cycle is performed with flooding the vacuum chamber with a first precursor. After finishing the first process cycle the vacuum chamber is actively flushed with a flushing fluid (like Nitrogen or the like) or a defined time period is allowed to elapse while the first precursor is extracted via a downstream. After that, the vacuum volume is considered to be clean for the next process cycle and the next cycle starts.

ALD steps as described above are typically performed on a time-controlled manner, i.e. each cycle runs for a pre-defined time period.

As a consequence, possible failures occurring during the processing result in product failures and are not recognised on their occurrence but mostly at any later point in time. Such failures may be caused by an existence of the first precursor when starting the second processing step due to insufficient downstream-extraction or a damage at an inlet valve which leads to insufficient concentration of a required precursor or the like. Furthermore, the time intervals may not be chosen optimal (as short as possible while still providing reliable processing steps) but may be set with unnecessary tolerances.

It is therefore an object of the present invention to provide an improved vacuum processing system which provides to overcome above-described disadvantages.

In particular, it is an object of the present invention to provide an improved vacuum processing system which provides performing of successive processing steps more efficiently (less time consuming).

Another object of the present invention is to provide an improved vacuum processing system which provides processing of substrates in more reliable manner over a comparatively larger number of process cycles.

These objects are achieved through the realisation of the characterizing features of the independent claims. Features that develop the invention further in alternative or advantageous manner can be gathered from the dependent claims.

The basic idea of the present invention is to provide a unit for determining state information regarding the inner atmosphere of a vacuum chamber (also called: vacuum volume, process volume, process chamber or processing chamber). The state information may be, but is not limited to, a chemical information with respect to the inner atmosphere. Such unit may be an atmospheric analyser which is used for determination of a concentration and/or of a composition of a fluid (e.g. gas or liquid) which is present in the vacuum chamber. The atmospheric analyser of course can also be used for checking if a defined fluid or defined chemical species is present or not.

The atmospheric analyser is arranged so that respective information can be obtained from inside of a vacuum chamber. For that, the atmospheric analyser may be arranged inside of the vacuum chamber or may be arranged in a way to receive respective data from inside, e.g. via a tube, via an optical fibre and/or via a transmission window.

The atmospheric analyser is part of a vacuum processing system which additionally comprises a controlling and/or regulating unit and a fluid application arrangement. The fluid application arrangement provides application of at least one defined fluid, like a precursor, into the processing chamber. The fluid application arrangement may be designed to be controllable by the controlling and/or regulating unit.

The controlling and/or regulating unit is connected (by wire or wirelessly) to the atmospheric analyser and to the fluid application arrangement. The controlling and/or regulating unit is further configured so that the fluid application arrangement can be controlled as a function of the information which can be provided by the atmospheric analyser.

Therefore, the present invention relates to a vacuum processing system comprising a vacuum chamber and a controllable fluid application arrangement which is connected to the vacuum chamber and which is configured to provide inflow of at least one fluid into the vacuum chamber in controlled manner. In particular, the vacuum processing system can comprise a downstream unit which is connected to the vacuum chamber and which is configured to provide extraction of a fluid or gas from the vacuum chamber.

The vacuum processing system also comprises a controlling and/or regulating unit for controlling at least the controllable fluid application arrangement.

Furthermore, the vacuum processing system comprises an atmospheric analyser. The atmospheric analyser is arranged and configured to determine atmospheric information from the inside of the vacuum chamber and to provide a respective atmospheric signal. The controlling and/or regulating unit is configured to control the controllable fluid application arrangement as a function of the atmospheric signal.

Advantageously, the vacuum processing system enables to control the inlet of a fluid into the chamber based on a determination of an actual atmospheric state inside of the chamber. By that, process cycles can be optimised with respect to time consumption for a single or for a number of processing steps. In other words, a successive processing step may be initiated not until a pre-defined atmospheric state is reached.

Alternatively or additionally, the vacuum processing system enables to check for proper operation of the system itself. Such can be realised by measuring or monitoring a concentration of a fluid or of a chemical species inside of the chamber and by comparing such measuring data with should-be data for the monitored fluid inflow. In case the compared data correspond, e.g. within limits of a pre-defined tolerance, the system or in particular the fluid application device can be considered properly operating.

In an embodiment of the vacuum processing system the controlling and/or regulating unit can comprise a pre-processing or checking functionality. The pre-processing functionality can be configured so that on its execution an inflow of a defined fluid into the vacuum chamber is provided by the controllable fluid application arrangement and a concentration of the defined fluid inside of the vacuum chamber is determined by the atmospheric analyser during inflow of the defined fluid, wherein the concentration of the defined fluid represents the atmospheric information.

The controlled application of the fluid and the respective determination of a related chemical concentration provides a basis for optimised control of processing steps, in particular for stopping a present processing step or for initiating a successive processing step.

In an embodiment of the invention the execution of the pre-processing functionality comprises further determination of the concentration of the defined fluid at least one-time after a defined time interval, the time interval begins with starting of the inflow of the defined fluid into the vacuum chamber. The determined concentration of the defined fluid is compared to a pre-threshold and a pre-processing information is provided as a function of that comparison.

According to an embodiment of the invention—on execution of the pre-processing functionality—the concentration of the defined fluid is continuously determined. The determined concentrations of the defined fluid are compared to a nominal concentration change for application of the defined fluid by the controllable fluid application arrangement and a pre-processing information is provided as a function of the comparison.

The comparison and/or the provision of the pre-processing information may be based on the atmospheric signal and processed e.g. on side of the controlling and/or regulating unit, or may be based directly on the atmospheric information and processed e.g. on side of the atmospheric analyser. In the latter case, the pre-processing information may be represented by the atmospheric signal. In other words, the controlling and/or regulating unit may be implemented in the atmospheric analyser or may be embodied as a separate unit. The above can be applied to any other functionality provided by the controlling and/or regulating unit.

In one embodiment of the invention the pre-processing information can provide information about a state of the controllable fluid application arrangement, about an operational reliability (proper operation) of the controllable fluid application arrangement and/or about a trigger point for starting a subsequent processing step.

Hence, the pre-processing functionality can provide either well defined control of a processing step or checking for system integrity. On the one hand, the pre-processing functionality enables to check if the fluid application unit, e.g. a gas inlet valve or mass flow controller which is arranged to control inflow of a precursor, works within defined limits, i.e. if the fluid application unit is damaged or comprises a malfunction. Such check can also be applied in order to determine an operation time or remaining lifetime of the fluid application unit. By that, predictive maintenance of the fluid application arrangement becomes available, i.e. the fluid application arrangement does not have to be replaces or serviced after a defined time or cycle interval but can be replaced or serviced on demand.

On the other hand, the pre-processing functionality enables to timely control initiating of a processing step, e.g. applying a discharge or igniting a plasma, as soon as a desired particle concentration is reached inside the chamber. By that, the desired processing step can be initiated as soon as possible to reliably obtain required product quality while avoiding any unnecessary application times, e.g. for guarantee a minimum particle concentration based on defined inlet-time for a respective precursor. This results in faster processing and shorter processing cycles while maintaining product quality.

In an embodiment of the present invention the controllable fluid application arrangement can be controlled as a function of the pre-processing information, wherein an inward flow of the defined fluid into the vacuum chamber is reduced and/or stopped. In other words, e.g. an inlet valve or mass flow controller can be controlled so that a gas (precursor) flow through the valve is reduced for instance when a target concentration is reached.

The pre-threshold may be a pre-defined value for a concentration of a defined chemical species or may be given by a concentration range which typically may comprise a tolerance band around an optimum (desired) concentration value. The pre-threshold may be represented by a change or progression of particle (molecule) concentration over a defined time period. The pre-threshold may be set or measured in advance of performing a particular processing step and/or may be measured during performing the particular processing step under well-defined nominal processing conditions.

According to an embodiment of the present invention the controlling and/or regulating unit can comprise a post-processing functionality. When the post-processing functionality is performed an atmospheric property (characteristic) inside of the vacuum chamber is determined by the atmospheric analyser, the determined atmospheric property is compared to a post-processing-threshold and the controllable fluid application arrangement is controlled as a function of the comparison of the determined atmospheric property with the post-processing-threshold.

The post-processing-threshold may be a pre-defined value for a concentration of a defined chemical species or may be given by a concentration range which typically may comprise a tolerance band around an optimum (desired) concentration value. The post-processing-threshold may be represented by a change or progression of particle (molecule) concentration over a defined time period. The post-processing-threshold may be set or measured in advance of performing a particular processing step and/or may be measured during performing the particular processing step under well-defined nominal processing conditions. The post-processing-threshold may represent a ratio of particular chemical elements (atoms, molecules or chemical species) relative to each other. The post-processing-threshold may comprise a list of chemical species allowed to be present in the vacuum chamber (whitelist). The other way round, the post-processing-threshold may alternatively or additionally comprise a list of chemical species not allowed to be present in the vacuum chamber (blacklist).

The atmospheric property can be represented by a concentration of the defined fluid, by a chemical composition concerning the inner atmosphere of the vacuum chamber and/or by a particular concentration or ratio of chemical elements or chemical molecules which are part of the chemical composition.

In one embodiment, the controllable fluid application arrangement is controlled (as a function of the comparison of the determined atmospheric property with the post-processing-threshold) so that an in-flow of the defined fluid into the vacuum chamber is reduced and/or stopped, and/or an inward flow of a further defined (different) fluid into the vacuum chamber is provided. By that, a successive processing step which requires application of another precursor can be initiated as soon as the concentration of a first precursor has fallen under a defined level (post-processing-threshold).

Hence, in an embodiment, on execution of the post-processing functionality, a subsequent processing step is triggered as a function of the comparison of the determined atmospheric property with the post-processing-threshold.

In particular, on execution of the post-processing functionality, the downstream unit can be controlled as a function of the comparison of the determined atmospheric property with the post-processing-threshold, wherein an flow rate for extraction of the fluid from the vacuum chamber is increased or reduced as a function of the comparison. This can be done in order to increase a fluid extraction rate, i.e. in order to reduce time (delay) between two successive processing steps. The downstream unit may comprise a controllable vacuum pump and/or a controllable vacuum valve, in particular a vacuum control valve.

According to an embodiment, the execution of the post-processing functionality can be triggered with starting and/or performing a defined processing step. This way, the defined processing step can be monitored and successive processing steps can be initiated in optimised manner (concerning time consumption) as described above.

In one embodiment of the present invention the concentration can be at least one of the following:
molar concentration of a chemical species,
mass per unit volume,
mass concentration,
volume concentration,
number density of molecules, and/or
percentage of substance amount.

In one embodiment, the controllable fluid application arrangement comprises at least two gas inlet valves or at least two mass flow controllers (MFC). In one embodiment, the controllable fluid application arrangement comprises at least one gas inlet valve and at least one mass flow controller (MFC). For instance, an MFC can be used for injection of gas and an inlet valve can be used for injection of a liquid precursor.

The invention also relates to a method for regulating a vacuum processing cycle in a vacuum chamber. The method comprises performing a first processing step. The first processing step comprises at least the steps of
providing a substrate to be processed in the vacuum chamber, the substrate having defined surface properties,
increasing a concentration of a first precursor inside of the vacuum chamber, the first precursor being designed to deposit onto the surface,
in particular applying a plasma inside of the vacuum chamber, and
reducing the concentration of the first precursor inside of the vacuum chamber after a defined time period.

Concerning the application of a plasma, this may be used for activation of a precursor. Alternatively, activation may be done by heat or increased temperature.

According to the method, the first processing step is repeated or a second processing step is initiated.

The method also comprises continuously determining the concentration of the first precursor inside the vacuum chamber and triggering the step of repeating the first processing step or initiating a second processing step as a function of the determined concentration of the first precursor.

In one embodiment of the invention the second processing step can be started as soon as the concentration of the first precursor inside the vacuum chamber has been determined fallen under a defined lower threshold, the lower threshold (post-processing-threshold) representing an acceptable residual concentration of the first precursor.

In particular, the second processing step can comprise inflowing of a second precursor into the vacuum chamber, the second precursor being different from the first precursor.

The invention also relates to a method for checking for proper operation of a vacuum processing system according to any one of the embodiments described above. The method comprises
providing a signal to the controllable fluid application arrangement to start defined inflow of the fluid into the vacuum chamber,
continuously determining the concentration of the fluid inside the vacuum chamber by means of the atmospheric analyser,
comparing the determined concentration with a reference concentration, the reference concentration representing a relationship between a should-be fluid inflow by means of the fluid application arrangement and a duration of the should-be fluid inflow, and
providing an information concerning an actual operation state of the fluid application arrangement based on the comparison of the determined concentration with the reference concentration.

The information concerning the actual operation state can thus provide information about proper operation within given limits or about the occurrence of a malfunction.

The invention also relates to a computer programme product comprising programme code which is stored on a machine-readable medium, or being embodied by an electromagnetic wave comprising a programme code segment, and having computer-executable instructions for performing and/or controlling any method described above, in particular when run on a vacuum processing system of above.

The devices and method according to the invention are described or explained in more detail below, purely by way of example, with reference to working examples shown schematically in the drawings. Specifically,

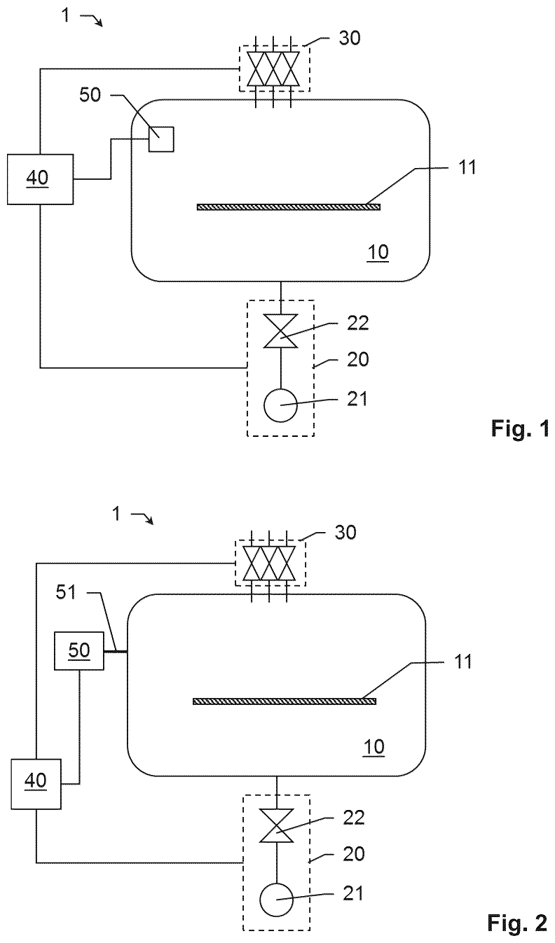

FIG. 1 shows a schematic representation of a first embodiment of a vacuum processing system according to the invention;

FIG. 2 shows another embodiment of a vacuum processing system according to the invention; and

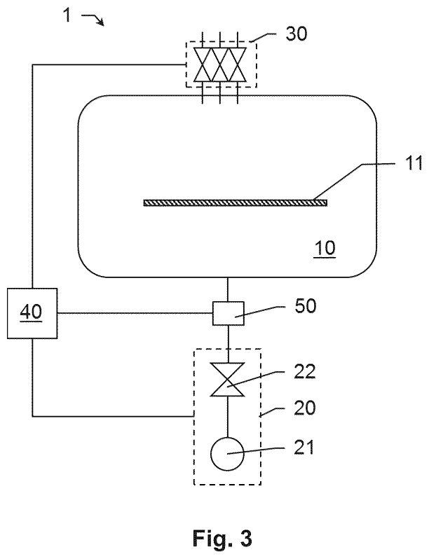

FIG. 3 shows another embodiment of a vacuum processing system according to the invention.

FIG. 1 shows an embodiment of a vacuum processing system 1 according to the invention.

The system 1 comprises a vacuum process chamber 10. The process chamber 10 is configured and designed to receive a substrate 11 or work piece to be processed, e.g. by means of an automated transportation system like a robot. The substrate 11 is brought into the vacuum chamber 10, a defined processing step is performed and, afterward, the processed substrate 11 is taken out of the vacuum chamber 10.

The system 1 also comprises a downstream unit 20 which is connected to the vacuum chamber 10. The downstream unit 20 is arranged and connected to the vacuum volume 10 to regulate a gas pressure inside of the vacuum volume 10. According to this embodiment, the downstream unit 20 comprises a vacuum pump 21 and a vacuum regulation valve 22. The vacuum pump 21 and/or the vacuum regulation valve 22 are designed as controllable components, which means that an actual suction output of the vacuum pump 21 and/or an actual cross section of a valve opening are variable upon applying a respective controlling signal. By such regulation a rate of fluid outflow out of the vacuum chamber 10 and cavity pressure can be varied and set.

Furthermore, the system 1 comprises a set of controllable inlet valves (here: three) which build a fluid application arrangement 30. The fluid application arrangement 30 is connected to the vacuum chamber 10 and configured to provide inflow of at least one fluid into the vacuum chamber 10 in controlled manner. In this embodiment the fluid application arrangement 30 is configured for controlling the application of three different fluids, in particular of three different precursors. Each of the inlet valves can be controlled individually, e.g. can be controlled to inject a respective precursor in pulsed manner for a defined time period.

A precursor may be gas or vapours of material which are carried by a carrier gas. Hence, in context or the present invention, a precursor is to be understood to be a fluid.

A controlling and/or regulating unit 40 is also provided. The controlling and/or regulating unit 40 is connected to the controllable fluid application arrangement 30 and to the downstream unit 20. By that, the amount of defined precursors which flow into the vacuum chamber 10 and defined points in time during a processing cycle for such inflow can be controlled. The vacuum pressure inside of the vacuum volume 10 can be controlled as well.

The vacuum processing system 1 comprises an atmospheric analyser 50. The atmospheric analyser 50 is arranged so and configured so that atmospheric information of inside of the vacuum chamber 10 can be determined. The analyser 50 may provide a respective atmospheric signal. As can be seen, the atmospheric analyser 50 is connected to the controlling and/or regulating unit 40. Respectively, the controlling and/or regulating unit 40 is configured to receive an information or signal which is provided by the atmospheric analyser 50.

The atmospheric analyser 50 may be built to determine a chemical composition and/or a concentration of a chemical element or species, in particular of a fluid or gas present inside of the process chamber 10.

The atmospheric analyser 50 may be an optical emission spectrometer (OES), a residual gas analyser (RGA) or a resonance spectrometer (RES).

A working principle of the atmospheric analyser 50 may be based on infrared (IR) or Raman spectroscopy, on gas chromatography (GC) or on another principle using electromagnetic waves or electromagnetic signals for analytical purpose (e.g. electron resonance).

The vacuum processing system 1 can be configured to check for proper operation of at least one component of the vacuum processing system 1. The component to be checked may preferably be the fluid application arrangement 30. Proper operation can be understood as precisely controlling an amount of inflow of a defined fluid into the vacuum chamber 10, wherein the amount of inflowing fluid corresponds to a known reference amount (target amount) for the fluid application arrangement 30 or for at least one gas inlet valve of the fluid application arrangement 30. In other words, the fluid application arrangement 30 is designed to provide precise amounts of fluids in the vacuum chamber 10 and the vacuum processing system 1 can be configured to check if provided amounts correspond to should-be amounts.

For checking that proper operation, the controlling unit 40 comprises a respective checking functionality. Such checking functionality provides and/or controls the following steps upon execution of the functionality: controlling a defined inflow of a defined fluid into the chamber 10; measuring a concentration of the inflowing fluid, in particular continuously; and comparing the measured concentration with the respective reference concentration.

The checking functionality may preferably be implemented as an algorithm and stored directly in the controlling unit 40, provided on a computer readable medium or remotely provided (as an electromagnetic wave), e.g. by a network or the internet. The same may apply of any other functionality provided by the controlling unit 40.

In case the measured concentration corresponds with the respective reference concentration, the fluid application arrangement 30 is considered to be of proper operation.

The reference concentration may be a range of concentration, i.e. may include a particular concentration tolerance.

In case the measured concentration does not correspond with the respective reference concentration, the fluid application arrangement 30 is considered to be not of proper operation, i.e. the application arrangement 30 is damaged or malfunctioning.

One advantage of this checking functionality relates to enabling improved supervision of quality and/or yield of the system 1. The sensor 50 (atmospheric analyser) supervising the concentration is able to directly detect if a fluid (e.g. gas precursor) is present in a process. If the fluid is detected as not present (no fluid or only a low concentration of the fluid is detected) such can be caused by a fault on one gas inlet valve. In consequence, this information can be directly feed to the controlling unit 40 or to a main tool controller and processing in the vacuum chamber 10 may be stopped to prevent loss of products.

Such type of process failure typically is very hard to detect. Standard ALD inlet valves may supervise directly only the actuator (drive) of the valve and not a respective membrane (which provides sealing inside of the valve) which is moved by the actuator, i.e. there is information available about the actuator but not about a state of the sealing element (membrane). If such sealing element is defect (e.g. because of sticking and not allowing the gas injection into process chamber) the resulting problem of gas failure is not easy to detect, in particular if carrier gas is used to carry the precursor. As long as such defect would not be detected, defective products (wavers) may be output.

The controlling and/or regulating unit 40 may further comprise a regulating functionality to control processing of a substrate in the processing chamber 10. The regulating functionality provides and/or controls the following steps upon execution of the functionality: providing a substrate to be processed in the vacuum chamber, the substrate having defined surface properties; increasing a concentration of a first precursor inside of the vacuum chamber, the first precursor being designed to deposit onto the surface; after a defined time period—reducing the concentration of the first precursor inside of the vacuum chamber. After performing of above steps a successive processing step may be performed.

In order to make sure that there does not occur any unwanted interactions between two different fluids (precursors) which are used in different processing steps, the regulating functionality provides controlling of fluid concentration and/or fluid composition of a first processing step and initiates the successive processing step as a function of the detected concentration and/or composition. Such separation of processing steps may be essential for reliably producing substrates by ALE/ALD.

By that, a high yield and productivity of such cyclic processes (ALD/ALE) becomes available. The information about precursor concentration and/or composition allows to optimise (e.g. shorten) process time of each recipe step (increase throughput) and to avoid unwanted (accidental) fluid mixing (e.g. of two or more precursors) to prevent particle issues. The functionality may be realised by a respective algorithm.

If a precursor to be used for the second processing step is introduced before concentration of a precursor to be used for the first processing step is not low enough or acceptable this can result in unwanted chemical reactions. This may lead to particle generation which is detrimental for semiconductor devices (e.g. affecting yield, resulting in wafer/chip scrap). Therefore, the regulating functionality provides to supervise respective precursor concentrations and to allow a next process step to start only if previous precursor reactant was removed and/or reduced below the defined concentration which is not causing any risk for planned production processes.

On the other hand, the controller does no longer have to supervise time periods of each processing step, in order to reach a given concentration of a precursor at an end point of each step. This means controlling of cyclic processing steps can be switched from time-based open loop control of processing devices (such as the fluid application arrangement 30) to concentration-determined closed loop control.

This results in optimised process sequences in regard of time. Overheads can be removed allowing higher throughput as the number of cycles can be finished faster (as soon as the measured concentration reaches a sufficient level).

The atmospheric analyser 50 can be used for detection of the concentration of different precursors. An output signal of the analyser 50 may also be added to the adaptive control of the vacuum control valve 22 (via the controller 40). The sensor signal intensity may be directly related to the concentration of precursor type spices. As soon as the concentration of a precursor spices is below a certain threshold allowed by process parameters then the next process step can start. If needed another fluid can be introduced to allow faster dilution and evacuation of a precursor.

FIG. 2 shows another embodiment of a vacuum processing system 1 according to the invention.

The vacuum processing system 1 differentiates from the one of FIG. 1 by the design and arrangement of the atmospheric analyser 50. The atmospheric analyser 50 is located outside of the vacuum chamber 10. In the present embodiment the atmospheric analyser 50 is an optical sensor which is configured to determine chemical compositions and/or chemical concentrations of a particular species by means of optical effects, e.g. scattering or absorption of light by an atom or molecule and emission of light.

The system 1 comprises an optical coupler 51 which connects the atmospheric analyser 50 with the processing chamber 10 and which provides bidirectional transmission of an electromagnetic signal, the electromagnetic signal may e.g. be measuring radiation, measuring light, a beam of light, collimated light, measuring laser light etc. The optical coupler 51 may comprise an optical fibre or an optical element, e.g. collimator, lens, aperture etc., which provides desired guidance of the electromagnetic signal.

In particular, the vacuum chamber 10 comprises a transmission window which allows bidirectional transmission of electromagnetic radiation of at least a particular measuring wavelength (of the electromagnetic signal). In particular, measuring light can be transmitted into the chamber 10 and a reflection or interaction of the measuring light can be detected outside of the chamber 10 by means of the transmission window.

FIG. 3 shows another embodiment of a vacuum processing system 1 according to the invention.

The vacuum processing system 1 of FIG. 3 differentiates from the one of FIG. 1 at least by the arrangement of the atmospheric analyser 50. The atmospheric analyser 50 is arranged between the vacuum chamber 10 and the downstream unit 20.

The atmospheric analyser 50 is designed to analyse a fluid flowing through the analyser 50. The atmospheric analyser 50 is preferably embodied as a residual gas analyser (RGA), i.e. configured as kind of a mass spectrometer. Hence, the atmospheric analyser 50 is designed to detect e.g. impurities or defined chemical species.

Although the invention is illustrated above, partly with reference to some specific embodiments, it must be understood that numerous modifications and combinations of different features of the embodiments can be made and that the different features can be combined with each other or with vacuum applications known from prior art.

1. A vacuum processing system comprising:
a vacuum chamber,
a controllable fluid application arrangement connected to the vacuum chamber and configured to provide inflow of fluid into the vacuum chamber in controlled manner; and
a controlling and/or regulating unit for controlling at least the controllable fluid application arrangement, wherein:
the vacuum processing system comprises an atmospheric analyzer,
the atmospheric analyzer is arranged and configured to determine atmospheric information of inside of the vacuum chamber and to provide the atmospheric information as a respective atmospheric signal, and
the controlling and/or regulating unit is configured to control the controllable fluid application arrangement as a function of the atmospheric signal.

2. The vacuum processing system according to claim 1, wherein:
the controlling and/or regulating unit comprises a pre-processing functionality on execution of which;
inflow of a defined fluid into the vacuum chamber is provided by the controllable fluid application arrangement, and
a concentration of the defined fluid inside of the vacuum chamber is determined by the atmospheric analyzer during inflow of the defined fluid, wherein the concentration of the defined fluid represents the atmospheric information.

3. The vacuum processing system according to claim 2, wherein:
on execution of the pre-processing functionality:
the concentration of the defined fluid is determined at least one-time after a defined time interval, the time interval begins with starting of the inflow of the defined fluid into the vacuum chamber,
the determined concentration of the defined fluid is compared to a pre-threshold, and
a pre-processing information is provided as a function of the comparison.

4. The vacuum processing system according to claim 2, wherein:
on execution of the pre-processing functionality;
the concentration of the defined fluid is continuously determined,
the determined concentrations of the defined fluid are compared to a nominal concentration change for application of the defined fluid by the controllable fluid application arrangement, and
a pre-processing information is provided as a function of the comparison.

5. The vacuum processing system according to claim 3, wherein:
the pre-processing information provides information about a state of the controllable fluid application arrangement, an operational reliability of the controllable fluid application arrangement and/or a trigger point for starting a subsequent processing step.

6. The vacuum processing system according to claim 3, wherein:
on execution of the pre-processing functionality the controllable fluid application arrangement is controlled as a function of the pre-processing information, wherein an inward flow of the defined fluid into the vacuum chamber is reduced and/or stopped.

7. The vacuum processing system according to claim 1, wherein:
the controlling and/or regulating unit comprises a post-processing functionality on execution of which:
an atmospheric property inside of the vacuum chamber is determined by the atmospheric analyzer,
the determined atmospheric property is compared to a post-processing-threshold, and
the controllable fluid application arrangement is controlled as a function of the comparison of the determined atmospheric property with the postprocessing-threshold.

8. The vacuum processing system according to claim 7, wherein:
the controllable fluid application arrangement is controlled so that:
an inward flow of the defined fluid into the vacuum chamber is reduced and/or stopped, and/or
an inward flow of a further defined fluid into the vacuum chamber is provided.

9. The vacuum processing system according to claim 7, wherein:
on execution of the post-processing functionality a downstream unit is controlled as a function of the comparison of the determined atmospheric property with the post-processing-threshold, wherein a flow rate for extraction of gas from the vacuum chamber is increased or reduced as a function of the comparison.

10. The vacuum processing system according to claim 7, wherein:
on execution of the post-processing functionality a subsequent processing step is triggered as a function of the comparison of the determined atmospheric property with the post-processing-threshold.

11. The vacuum processing system according to claim 7, wherein:
the execution of the post-processing functionality is triggered by starting and/or performing a defined processing step.

12. The vacuum processing system according to claim 7, wherein:
the atmospheric property is represented by:
a concentration of the defined fluid,
a chemical composition concerning the inner atmosphere of the vacuum chamber, and/or
particular concentrations of chemical elements or chemical molecules which are part of the chemical composition.

13. The vacuum processing system according to claim 2, wherein:
the concentration being at least one of the following:
molar concentration of a chemical species,
mass per unit volume,
mass concentration,
volume concentration,
number density of molecules, and/or
percentage of substance amount.

14. The vacuum processing system according to claim 1, wherein:
the controllable fluid application arrangement comprises;
at least one gas inlet valve and at least one mass flow controller; or
at least two gas inlet valves or at least two mass flow controllers.

15. The vacuum processing system according to claim 1, wherein:
the vacuum processing system comprises a downstream unit connected to the vacuum chamber and configured to provide extraction of fluid from the vacuum chamber.

16. A method for regulating a vacuum processing cycle in a vacuum chamber, comprising:
performing a first processing step, the first processing step comprising:
providing a substrate to be processed in the vacuum chamber, the substrate having defined surface properties,
increasing a concentration of a first precursor inside of the vacuum chamber, the first precursor being designed to deposit onto the surface, in particular applying a plasma inside of the vacuum chamber, and
reducing the concentration of the first precursor inside of the vacuum chamber after a defined time period, and
repeating the first processing step or initiating a second processing step, comprising:
continuously determining the concentration of the first precursor inside the vacuum chamber, and
triggering the step of repeating the first processing step or initiating a second processing step as a function of the determined concentration of the first precursor.

17. The method according to claim 16, wherein:
the second processing step is started as soon as the concentration of the first precursor inside the vacuum chamber has fallen under a defined lower threshold, the lower threshold representing an acceptable residual concentration of the first precursor.

18. The method according to claim 17, wherein:
the second processing step comprises inflowing of a second precursor into the vacuum chamber, the second precursor being different from the first precursor.

19. A method for checking for proper operation of a vacuum processing system, the method comprising:
providing a signal to the controllable fluid application arrangement to start defined inflow of the fluid into the vacuum chamber; and
continuously determining the concentration of the fluid inside the vacuum chamber by means of the atmospheric analyzer:
comparing the determined concentration with a reference concentration, the reference concentration;
representing a relationship between a should-be fluid inflow by means of the fluid application arrangement and a duration of the should-be fluid inflow; and
providing an information concerning an actual operation state of the fluid application arrangement based on the comparison of the determined concentration with the reference concentration.

20. A computer program product comprising program code which is stored on a machine-readable medium, or being embodied by an electromagnetic wave comprising a program code segment, and having computer-executable instructions for performing and/or controlling the method according to claim 16.
